(19) United States
(12) Patent Application Publication
(10) Pub. No.: US 2014/0203329 A1
(43) Pub. Date: Jul. 24, 2014

(54) NITRIDE ELECTRONIC DEVICE AND METHOD FOR FABRICATING NITRIDE ELECTRONIC DEVICE

(71) Applicants: Yu Saitoh, Itami-shi (JP); Masaya Okada, Osaka-shi (JP); Yusuke Yoshizumi, Itami-shi (JP); Makoto Kiyama, Itami-shi (JP); Masaki Ueno, Itami-shi (JP); Koji Katayama, Osaka-shi (JP); Takao Nakamura, Itami-shi (JP)

(72) Inventors: Yu Saitoh, Itami-shi (JP); Masaya Okada, Osaka-shi (JP); Yusuke Yoshizumi, Itami-shi (JP); Makoto Kiyama, Itami-shi (JP); Masaki Ueno, Itami-shi (JP); Koji Katayama, Osaka-shi (JP); Takao Nakamura, Itami-shi (JP)

(73) Assignee: Summitomo Electric Industries, Ltd., Osaka-shi (JP)

(21) Appl. No.: 14/123,738

(22) PCT Filed: Jun. 3, 2011
(86) PCT No.: PCT/JP2011/062836

§ 371 Date: Jan. 31, 2014

(51) Int. Cl. H01L 29/66; H01L 29/778

(52) U.S. Cl. CPC H01L 29/66462; H01L 29/7788
USPC 257/194; 438/172

(57) ABSTRACT

Provided is a nitride electronic device having a structure that allows the reduction of leakage by preventing the carrier concentration from increasing in a channel layer. An inclined surface and a primary surface of a semiconductor stack extend along first and second reference planes R1, R2, respectively. The primary surface of the stack is inclined at an angle ranging from 5 to 40 degrees with respect to a reference axis indicating a c-axis direction of hexagonal group III nitride. An axis normal to the plane R1 and the axis form an angle smaller than the angle an axis normal to the plane R2 and the axis form. The oxygen concentration of the channel layer is lower than 1×10¹⁷ cm⁻³. It becomes possible to avoid increase in carrier concentration of the channel layer caused by the oxygen addition, thereby reducing leakage current via the channel layer in the transistor.

### TECHNICAL FIELD

The present invention relates to a nitride electronic device and to a method for fabricating a nitride electronic device.

### BACKGROUND ART

Patent Literature 1 discloses a semiconductor device. This semiconductor device can improve pinch-off characteristics or can enhance the mobility of the channel layer to have good electric properties.

### CITATION LIST

### Patent Literature

Patent Literature 1: Japanese Patent Application Publication No. 2006-286941

### SUMMARY OF INVENTION

### Technical Problem

For instance, a nitride electronic device comprises a semiconductor region formed on a substrate. The semiconductor region comprises an opening section on a main surface thereof. A channel layer and a carrier supply layer are re-grown on the main surface of the semiconductor region and the side surface of the opening section. The carrier supply layer is formed on the channel layer, such that these layers form a heterojunction. A gate electrode is formed on the carrier supply layer located on the side surface of the opening section. A source electrode is formed on the main surface of the semiconductor region.

The channel layer is thus grown on the main surface of the semiconductor stack and on the side surface of the opening section. The channel layer is made of an undoped gallium nitride-based semiconductor. When the semiconductor layer is grown on the main surface of the semiconductor region and on the side surface of the opening section, growth on the main surface of the semiconductor region is different from growth on the side surface of the opening section depending upon the difference in surface orientation between the main surface and the inclined surface. When the semiconductor stack is grown on a c-plane substrate, the semiconductor region grows substantially planarly on the c-plane substrate, so that the main surface of the semiconductor region grown thereon constitutes a flat surface (substantially a c-plane).

When the opening is formed in the semiconductor region as described above and then the channel layer is grown on the main surface of the semiconductor stack and the side surface of the opening section, the growth surface in the main surface is made up of a C-plane or a vicinal surface thereof at the early stage of growth of the channel layer. In such a growth surface, the restricted incorporation of raw materials occurs during growth of the gallium nitride-based semiconductor. Group III atoms that are not incorporated into the flat surface move from the main surface in the semiconductor region to reach the side surface of the opening, and the incorporation of many atoms occurs at that region. In the growth of the side surface (the inclination surface that is inclined with respect to the flat surface) of the opening, the growth rate in the direction vertical to the C-plane is very high, and during this epitaxial growth, a greater number of oxygen atoms are incorporated by virtue of the growth direction. Since the incorporation of oxygen occurs during the growth of an undoped channel layer, electron carriers are generated in the channel layer as a result of oxygen addition. This constitutes a cause of drain leakage of transistor.

Growth of the channel layer at a low growth temperature can reduce a growth rate in the C-axis vertical direction. Lowering of the growth temperature makes it possible to promote incorporation of raw material into the C-plane surface, and, as a result, to relatively reduce the incorporation into the side surface (inclination surface) of the semiconductor stack.

From the viewpoint of the crystallinity of the carrier supply layer, the optimal growth temperature of the carrier supply layer is higher than that of the channel layer. Accordingly, a reduction in the growth temperature of the channel layer involves a longer transition period of time for temperature change from the growth temperature of the channel layer to the growth temperature of the carrier supply layer. This lengthening of the growth interruption period of time gives rise to migration of substances on the surface of the channel layer that is exposed to the high-temperature atmosphere, while the surface shape of the channel layer that is grown on the side surface of the opening collapses on account of deformation with respect to the shape of the underlying semiconductor region. This results in that lowering of the growth temperature in order to reduce oxygen incorporation is restricted by certain constraints.

If the growth interruption time is shortened through shortening of the transition period, the crystallinity of the carrier supply layer may be deteriorated and the abruptness of the hetero-interface may also be deteriorated because the growth of the carrier supply layer starts before the substrate temperature has been sufficiently stabilized. This translates into an increase of the on-resistance of the device.

It is an object of the present invention, which is made in the light of the above considerations, to provide a method for fabricating a nitride electronic device that allows the reduction of leakage caused by an increase in the carrier concentration of a channel layer. It is another object of the invention to provide a nitride electronic device having a structure that allows the reduction of leakage through avoidance of an increase in the carrier concentration of the channel layer.

### Solution to Problem

An invention according to an aspect of the present invention relates to a method for fabricating a nitride electronic device. The method comprises the steps of: (a) growing a semiconductor stack on a primary surface of a substrate; (b) forming a mask on the semiconductor stack; (c) etching the semiconductor stack using the mask to form an opening in the primary surface of the semiconductor stack, the opening having an inclined surface with respect to a primary surface of the semiconductor stack; and (d) after removal of the mask, supplying a raw material gas to a growth reactor to grow a channel layer on the primary surface and the inclined surface of the semiconductor stack at a first growth temperature, the raw material gas containing ammonia and a group III element raw material. The primary surface of the substrate is made of a hexagonal-system group III nitride; the semiconductor stack comprises a drift layer made of a first gallium nitride-based semiconductor, a current blocking layer made of a second gallium nitride-based semiconductor and a contact layer made of a third gallium nitride-based semiconductor; the channel layer comprises an undoped gallium nitride-based semiconductor; the inclined surface and the primary surface of the semiconductor stack extend along first and second reference planes, respectively; a vector normal to the primary surface of the semiconductor stack is inclined at an angle ranging from 5 degrees to 40 degrees with respect to a reference axis that denotes a c-axis direction of the hexagonal-system group III nitride; and an angle that the reference axis and a vector normal to the first reference plane form is smaller than an angle that the reference axis and a line normal to the second reference plane form.

In this fabricating method, growth on primary surface of the semiconductor stack differs from growth on the inclined surface of the semiconductor stack, depending upon differences in the inclination angle with respect to the c-axis. However, the primary surface of the semiconductor stack is inclined at an angle ranging from 5 degrees to 40 degrees with respect to the reference axis, and the angle formed by the reference axis (c-axis) and the normal vector of the first reference plane (plane along which the inclined surface of the semiconductor stack extends) is smaller than the angle formed by the reference axis (c-axis) and the normal vector of the second reference plane (plane along which the primary surface of the semiconductor stack extends). Accordingly, growth onto the inclined surface of the semiconductor stack is closer to the growth onto the c-plane than that onto the primary surface of the semiconductor stack. This allows therefore reducing the degree of oxygen incorporation in the growth on the inclined surface of the semiconductor stack. It becomes possible to avoid increases in carrier concentration caused by oxygen addition in the channel layer and to reduce transistor channel leakage.

A nitride electronic device according to another aspect of the present invention comprises: (a) a support base that is made of a hexagonal-system group III nitride and has a primary surface that is inclined by an angle ranging from 5 degrees to 40 degrees with respect to a c-axis of the hexagonal-system group III nitride; (b) a semiconductor stack comprising a drift layer, a current blocking layer and a contact layer, which are sequentially provided on the primary surface of the support base, the semiconductor stack having an opening extending from the contact layer up to the drift layer via the current blocking layer; (c) a channel layer provided on a side surface of the opening, the channel layer comprising a gallium nitride-based semiconductor; (d) a carrier supply layer provided on the side surface of the opening, the carrier supply layer comprising a group III nitride; (e) a gate electrode provided on the side surface of the opening; (f) a source electrode provided on a primary surface of the semiconductor stack; and (g) a drain electrode provided on any one of the semiconductor stack and the support base. An oxygen concentration of the channel layer is lower than 1×10¹⁷ cm⁻³; the side surface and the primary surface of the semiconductor stack extend along first and second reference planes, respectively; a vector normal to the primary surface of the semiconductor stack is inclined at an angle ranging from 5 degrees to 40 degrees with respect to a plane that is perpendicular to a reference axis indicating the c-axis direction of the hexagonal-system group III nitride; an angle formed by the reference axis and a line normal to the first reference plane is smaller than an angle formed by the reference axis and a line normal to the second reference plane; the drift layer is made of a first gallium nitride-based semiconductor; the current blocking layer is made of a second gallium nitride-based semiconductor; the contact layer is made of a third gallium nitride-based semiconductor; the channel layer is provided between the carrier supply layer and the side surface of the opening; and the bandgap of the group III nitride of the carrier supply layer is greater than the bandgap of the gallium nitride-based semiconductor of the channel layer.

In this nitride semiconductor element, the inclined surface and the primary surface of the semiconductor stack extend along the first and second reference planes, respectively, and the normal vector of the primary surface of the semiconductor stack is inclined by an angle ranging from 5 degrees to 40 degrees with respect to a reference axis that indicates the c-axis direction of the hexagonal-system group III nitride. The angle formed by the reference axis and the normal vector of the first reference plane is smaller than the angle formed by the reference axis and the normal line of the second reference plane. Therefore, the oxygen concentration of the channel layer can be made lower than 1×10¹⁷ cm⁻³. It becomes possible to prevent the carrier concentration in the channel layer from increasing due to the oxygen addition, and to reduce transistor channel leakage.

Preferably, the one aspect of the present invention further comprise the steps of: (e) after growth of the channel layer, raising a substrate temperature from the first growth temperature to a second growth temperature, and (f) growing, on the channel layer, a carrier supply layer at the second growth temperature to form a substrate product. The carrier supply layer comprises a group III nitride semiconductor; the bandgap of the group III nitride semiconductor of the carrier supply layer is greater than the bandgap of the gallium nitride-based semiconductor of the channel layer; the channel layer comprises a first portion and a second portion, and the first portion is grown on the inclined surface of the semiconductor stack and the second portion is grown on the primary surface of the semiconductor stack; the carrier supply layer comprises a first portion and a second portion, and the first portion is grown on the first portion of the channel layer and the second portion is grown on the second portion of the channel layer; the first portion of the carrier supply layer is inclined with respect to the second reference plane; and a vector normal to the second reference plane is inclined by an angle ranging from 5 degrees to 40 degrees with respect to a reference axis that denotes a c-axis direction of the first gallium nitride-based semiconductor.

In the one aspect of the present invention, a normal vector of the second reference plane is inclined by an angle ranging from 5 degrees to 40 degrees with respect to a reference axis that denotes a c-axis direction of the third gallium nitride-based semiconductor. As a result, it becomes possible to reduce the degree of oxygen uptake in the growth onto the inclined surface of the semiconductor stack without lowering of the growth temperature of the channel layer. Further, the period of time over which the substrate temperature is raised from the first growth temperature to the second growth temperature is not prolonged because the channel layer is grown without lowering of the growth temperature thereof. Accordingly, it becomes possible to reduce migration of atoms on the surface of the channel layer during the raise in temperature, thereby avoiding deformation of the channel layer surface.

Further, the substrate temperature can be sufficiently stabilized to the second growth temperature without lengthening of the period of time over which the substrate temperature is changed from the first growth temperature to the second growth temperature. A hetero-interface between the channel layer and the carrier supply layer becomes thus formed after the substrate temperature has sufficiently stabilized to the second temperature. Accordingly, it becomes possible to avoid formation of a hetero-interface of low quality.

In the one aspect and the other aspect of the present invention, preferably, the oxygen concentration of the first portion of the channel layer is lower than 1×10¹⁷ cm⁻³. This manufacturing method allows reducing transistor leakage caused by the oxygen concentration of the channel layer.

In the one aspect and the other aspect of the present invention, preferably, the inclined surface of the semiconductor stack forms an angle in a range larger than −10 degrees and smaller than +10 degrees with respect to a plane that is perpendicular to the reference axis. In the one aspect and the other aspect of the present invention, unevenness of the thickness of the channel layer can be reduced if the inclined surface of the semiconductor stack is within the above angle range.

The one aspect and the other aspect of the present invention may further comprise the step of, after retrieval of the substrate product, forming a gate electrode on the carrier supply layer. The inclined surface of the opening comprises a side surface of the drift layer, a side surface of the current blocking layer and a side surface of the contact layer. The side surface of the current blocking layer is inclined by an angle ranging from 5 degrees to 40 degrees with respect to the second portion that is grown on the primary surface of the semiconductor stack. The gate electrode is provided on the side surface of the current blocking layer.

In the one aspect and the other aspect of the present invention, the normal line of the side surface of the current blocking layer is inclined by an angle of 5 degrees or more with respect to the reference axis. This allows avoiding increases in on-resistance derived from increases in channel length. When the substrate has a crystal orientation set to an angle of 40 degrees or less with respect to the C-axis, and the normal vector of the current blocking layer is set to an angle of 40 degrees or less, it becomes possible to reduce the contamination of oxygen caused by nitrogen, located in the growth surface, during epitaxial growth of the underlying section carried out prior to formation of the opening section by RIE, and it becomes possible to prevent drops of the breakdown voltage of the pn-diode, which the channel layer and the current blocking layer form, due to the both influences of acceptor compensation in the current blocking layer and of excess donors in the channel layer.

In the one aspect and the other aspect of the present invention, the step of forming the mask on the semiconductor stack may further comprise the steps of forming a pattern on a resist that is coated onto the semiconductor stack, the pattern having an edge that defines the opening, and forming a sloping surface at the edge through thermal treatment of the patterned resist to form the mask. In the etching, the mask and the semiconductor stack are etched by dry etching.

In the one aspect and the other aspect of the present invention, the thermal treatment of a patterned resist is carried out to form a sloping surface at an edge thereof, thereby forming a mask. The angle of the inclined surface of the opening can thus be easily adjusted.

In the one aspect and the other aspect of the present invention, the substrate is formed of a conductive free-standing group III nitride substrate; and a line normal to a primary surface of the free-standing group III nitride substrate is inclined at an angle ranging from 5 degrees to 40 degrees with respect to the plane perpendicular to a reference axis, and the reference axis denotes a c-axis direction of the hexagonal-system group III nitride. The method may further comprise the step of forming a drain electrode on a back side of the substrate.

In the one aspect and the other aspect of the present invention, the primary surface of the free-standing group III nitride substrate is inclined at an angle within the above angle range, and hence the primary surface and the inclined surface of the semiconductor stack can be formed easily.

In the one aspect and the other aspect of the present invention, preferably, a combination of the first gallium nitride-based semiconductor for the drift layer, the second gallium nitride-based semiconductor for the current blocking layer and the third gallium nitride-based semiconductor for the contact layer encompasses as follow: n-type GaN/p-type GaN/n⁺-type GaN; and n-type GaN/p-type AlGaN/n⁺-type GaN. The one aspect and the other aspect of the present invention provide an excellent combination of drift layer, current blocking layer and contact layer as listed above.

In the one aspect and the other aspect of the present invention, the material of the channel layer and the carrier supply layer may encompass as follows: InGaN/AlGaN; GaN/AlGaN; and AlGaN/AlN. The one aspect and the other aspect of the present invention, provide an excellent combination of a channel layer and a carrier supply layer as listed above.

The one aspect and the other aspect of the present invention may further comprise the step of, after taking out the substrate product from the growth reactor, forming a source electrode on the primary surface of the semiconductor stack. The source electrode can supply potential to the current blocking layer and the contact layer; the channel layer and the carrier supply layer can form a junction; a two-dimensional electron gas layer can be formed in the junction; and the source electrode can supply carriers that flow through the channel layer. In the one aspect and the other aspect of the present invention, the source electrode supplies potential to the current blocking layer and the contact layer, and hence the current blocking layer functions as a back gate to the channel layer.

The one aspect and the other aspect of the present invention may further comprise the step of forming a gate electrode that forms a junction with the first portion of the carrier supply layer. The one aspect and the other aspect of the present invention can provide a transistor that can control channel carriers by use of a gate electrode forming a Schottky junction with the semiconductor.

The one aspect and the other aspect of the present invention may further comprise the steps of forming a gate insulating film on the first portion of the carrier supply layer, and forming a gate electrode on the gate insulating film. The gate electrode forms a junction with the gate insulating film. The one aspect and the other aspect of the present invention can provide a transistor having a gate electrode that can control channel carriers through the insulating film.

In the one aspect and the other aspect of the present invention, it is preferable that the first gallium nitride-based semiconductor for the drift layer comprise Si-doped n-type GaN; the thickness of the drift layer ranges from 1 μm to 10 μm; the Si concentration of the first gallium nitride-based semiconductor ranges from 1×10¹⁵ cm⁻³ to 3×10¹⁶ cm⁻³; the second gallium nitride-based semiconductor for the current blocking layer comprise Mg-doped p-type GaN; the thickness of the current blocking layer ranges from 0.1 μm to 2.0 μm; the Mg concentration of the second gallium nitride-based semiconductor ranges from 5×10¹⁶ cm⁻³ to 5×10¹⁸ cm⁻³; the third gallium nitride-based semiconductor for the contact layer comprises Si-doped n-type GaN; the thickness of the contact layer ranges from 0.1 μm to 1.0 μm; and the Si concentration of the third gallium nitride-based semiconductor is 1×10¹⁶ cm⁻³ or higher. In the one aspect and the other aspect of the present invention, the semiconductor stack that comprises gallium nitride-based semiconductors having the above values can provide the transistor with superior characteristics.

In the one aspect and the other aspect of the present invention, the carrier supply layer may comprise Al_{X}Ga_{1-X}N (0<X<1); the thickness of the carrier supply layer may range from 5 nm to 40 nm; the channel layer may comprise undoped GaN; and the thickness of the channel layer may range from 20 nm to 400 nm. In the one aspect and the other aspect of the present invention, when the carrier supply layer and the channel layer have a region, located between the gate electrode and the current blocking layer, in which the above values are achieved, the transistor can be provided with superior characteristics.

In the nitride electronic device according to the one aspect and the other aspect of the present invention, the side surface of the semiconductor stack can form an angle in a range larger than −10 degrees and smaller than +10 degrees with respect to the plane that is perpendicular to the reference axis. In this nitride electronic device, when the side surface of the semiconductor stack is within the above angle range, the uniformity of the thickness of the channel layer can be enhanced.

In the nitride electronic device according to the one aspect and the other aspect of the present invention, the gate electrode can form a junction with the carrier supply layer. The carrier supply layer and channel layer are provided between the gate electrode and the current blocking layer. The one aspect and the other aspect of the present invention can provide a transistor that can control channel carriers by use of a gate electrode that forms a Schottky junction with a semiconductor.

Alternatively, the nitride electronic device according to the one aspect and the other aspect of the present invention may further comprise a gate insulating film which is provided on the carrier supply layer. The gate electrode forms a junction with the gate insulating film. The carrier supply layer and the channel layer are provided between the gate insulating film and the current blocking layer. The one aspect and the other aspect of the present invention can provide a transistor having a gate electrode that can control channel carriers through an insulating film.

The abovementioned object as well as other objects, features and advantages of the present invention will be made apparent more easily on the basis of the detailed description of preferred embodiments of the present invention as set forth below with reference to accompanying drawings.

### Advantageous Effects of Invention

As explained above, one aspect of the present invention can provide a method for fabricating a nitride electronic device that allows reducing leakage caused by an increase in carrier concentration in a channel layer. Further, another aspect of the present invention can provide a nitride electronic device having a structure that allows reducing leakage through avoidance of increases in carrier concentration in the channel layer.

### BRIEF DESCRIPTION OF DRAWINGS

FIG. 1 is a diagram illustrating the structure of a heterojunction transistor according to the present embodiment;

FIG. 2 is a diagram illustrating a flowchart that includes the major processes of a method for fabricating a heterojunction transistor according to the present embodiment;

FIG. 3 is a view showing schematic diagrams that illustrate a major process of a method for fabricating a heterojunction transistor according to the present embodiment;

FIG. 4 is a view showing schematic diagrams that illustrate a major process of a method for fabricating a heterojunction transistor according to the present embodiment;

FIG. 5 is a view showing schematic diagrams that illustrate a major process of a method for fabricating a heterojunction transistor according to the present embodiment;

FIG. 6 is a view showing schematic diagrams that illustrate a major process of a method for fabricating a heterojunction transistor according to the present embodiment;

FIG. 7 is a view showing diagrams for explaining inclination of a side surface of an opening section and uniformity of the thickness of the channel layer;

FIG. 8 is a diagram illustrating a re-growth temperature sequence which shows the growth of a channel layer and a carrier supply layer; and

FIG. 9 is a view showing diagrams that illustrate a re-growth mechanism of crystal at a physically-formed underlying surface.

### DESCRIPTION OF EMBODIMENTS

The teachings of the present invention can be easily understood by referring to the below-described detailed description and accompanying exemplary drawings. Embodiments of the nitride electronic device and method for fabricating a nitride electronic device of the present invention will be explained below with reference to accompanying drawings. If possible, identical portions will be denoted with identical reference numerals.

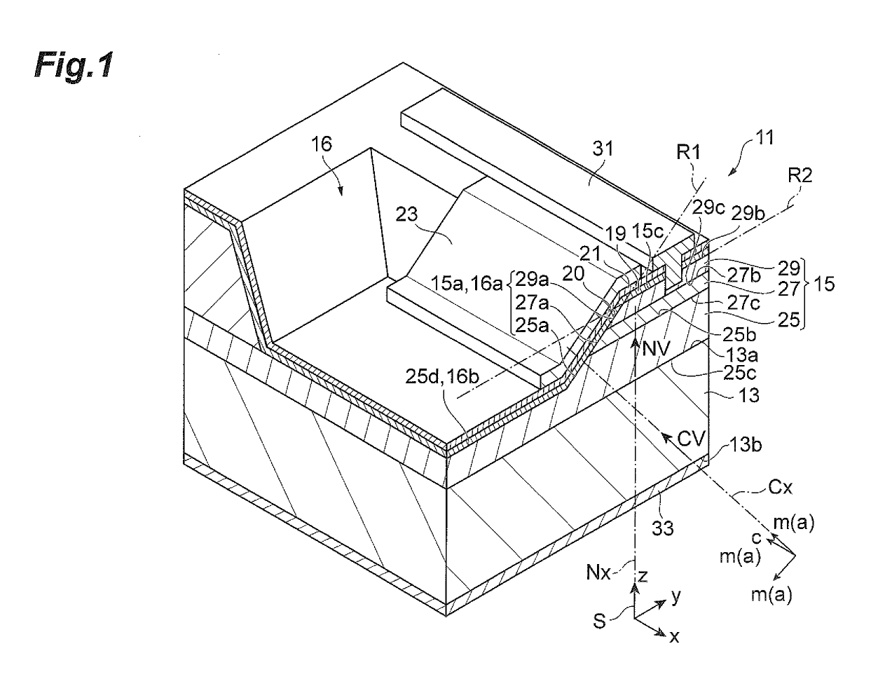

FIG. 1 is a diagram illustrating the structure of a heterojunction transistor according to the present embodiment. A heterojunction transistor 11 comprises a conductive support base 13, a semiconductor stack 15, a channel layer 19, a carrier supply layer 21 and a gate electrode 23. The support base 13 includes a semipolar primary surface 13a and a rear surface 13b. The primary surface 13a comprises a hexagonal-system group III nitride. The primary surface 13a is inclined at an angle in the range of 5 degrees to 40 degrees with respect to a reference axis (Cx (c-axis vector) CV) that extends in the direction of the c-axis of the hexagonal-system group III nitride. Accordingly, the normal axis (normal vector NV) Nx of the primary surface 13a is inclined at an angle of the above angle inclined with respect to the reference axis Cx. The semiconductor stack 15 has an opening section 16. The opening section 16 has a bottom section 16b that is spaced apart from the primary surface 13a of the support base 13. The opening section 16 is defined by a mesa, recess or groove formed in the semiconductor stack 15. The channel layer 19 comprises a gallium nitride-based semiconductor and is provided in the opening section 16 of the semiconductor stack 15. The carrier supply layer 21, which comprises a group III nitride, is provided in the opening section 16 of the semiconductor stack 15 and extends on the channel layer 19 in the opening section 16.

The bandgap of the group III nitride semiconductor of the carrier supply layer 21 is greater than the bandgap of the gallium nitride-based semiconductor of the channel layer 19. The gate electrode 23 is provided on the carrier supply layer 21. The carrier supply layer 21 is positioned between the channel layer 19 and the gate electrode 23 in the opening section 16. The gate electrode 23 is provided on a side surface 16a of the opening section 16, and controls carrier conduction in the channel layer 19. The channel layer 19 and the carrier supply layer 21 form a heterojunction 20. The gate electrode 23 controls creation of a two-dimensional electron gas along the heterojunction 20.

The semiconductor stack 15 includes a drift layer 25 that comprises a first conductivity type gallium nitride-based semiconductor layer, a current blocking layer 27 that comprises a second conductivity type gallium nitride-based semiconductor layer, and a contact layer 29 that comprises a first conductivity type gallium nitride-based semiconductor layer. The drift layer 25 is, for instance, a Si-doped n-type semiconductor, and is provided on the primary surface 13a of the substrate 13. The current blocking layer 27 has for instance p-conductivity, and is provided between the contact layer 29 and the drift layer 25. The contact layer 29 is provided between the current blocking layer 27 and the support base 13. The contact layer 29 can be, for instance, an n-conductivity semiconductor. The semiconductor stack 15 has a configuration of an npn structure.

The drift layer 25 has an end surface 25a that is positioned on the side surface 16a and the bottom surface 16b of the opening section 16 of the semiconductor stack 16. The current blocking layer 27 has an end surface 27a that is positioned on the side surface 16a of the opening section 16 of the semiconductor stack 15. The contact layer 29 has an end surface 29a that reaches the side surface 16a of the opening section 16 of the semiconductor stack 15. The channel layer 19 is provided on the end surface 25a and a top surface 25d of the drift layer 25, the end surface 27a of the current blocking layer 27, and the end surface 29a of the contact layer 29.

An inclined surface 15a and a primary surface 15c of the semiconductor stack 15 extend along first and second reference planes R1 and R2, respectively. The primary surface 15c of the semiconductor stack 15 is inclined at an angle ranging from 5 degrees to 40 degrees with respect to the reference axis Cx that denotes the c-axis direction of the hexagonal-system group III nitride. The angle formed by the reference axis Cx and the axis normal to the first reference plane R1 is smaller than the angle formed by the reference axis Cx and the axis normal to the second reference plane R2. The channel layer 19 has a portion that is provided on the inclination surface 15a of the semiconductor stack 15. This portion is positioned between the gate electrode 23 and the end surface 27a of the current blocking layer 27. The oxygen concentration of this portion is lower than 1×10¹⁷ cm⁻³.

In the heterojunction transistor 11, the inclined surface 15a and the primary surface 15c of the semiconductor stack 15 extend along the first and second reference planes R1 and R2, respectively. The primary surface 15c of the semiconductor stack 15 is inclined at the angle that ranges from 5 degrees to 40 degrees with respect to the reference axis Cx that denotes the c-axis direction of the hexagonal-system group III nitride. Moreover, the angle formed by the reference axis Cx and the normal line of the first reference plane R1 is smaller than the angle formed by the reference axis Cx and the normal line of the second reference plane R2. Therefore, the oxygen concentration of the channel layer 19 can be set to be lower than 1×10¹⁷ cm⁻³. Accordingly, it becomes possible to avoid increases in carrier concentration in the channel layer 19 which is caused by oxygen incorporation, and to reduce transistor leakage current via the channel layer.

In the heterojunction transistor 11, preferably, the inclined surface 15a of the semiconductor stack 15 forms an angle in a range larger than −10 degrees and smaller than +10 degrees with respect to the plane that is perpendicular to the reference axis Cx. The inclined surface 15a of the semiconductor stack 15 that is inclined the above angle range can form a channel layer having desired characteristics (for instance, carrier concentration), and can improve the uniformity of the channel layer thickness.

In a preferred example, as illustrated in FIG. 1, the side surface 15a of the opening section 15 is provided along the plane that is perpendicular or substantially perpendicular to the c-axis. In FIG. 1, a crystal coordinate system CR is depicted, and in the drawing, a reference axis Cx denotes the direction of the c-axis. The m-plane is a plane perpendicular to the m-axis in the crystal coordinate system CR, and the a-plane is a plane perpendicular to the a-axis in the crystal coordinate system CR. The side surface 16a of the opening section 16 forms a first angle with respect to the a-plane of the group III nitride semiconductor, forms a second angle with respect to the m-plane of the group III nitride semiconductor, and forms a third angle with respect to the c-plane of the group III nitride semiconductor. These angles are defined as angles formed by the lines normal to the respective planes and the normal line of the surface. On the basis of such a definition, the third angle is smaller than the first angle, and is smaller than the second angle.

The heterojunction transistor 11 can further comprise a source electrode 31 in direct contact with the contact layer 25. The source electrode 31 is connected in such a way so as to supply carriers to the current blocking layer. In order that the source electrode 31 supplies electric potential not only to the contact layer 25 but also to the current blocking layer 27, the potential of the current blocking layer 27 is applied through the source electrode 31, and the applied potential acts as back bias. This back bias is suitable for the normally-off operation of the heterojunction transistor 11.

The heterojunction transistor 11 can further comprise a drain electrode 33 that is provided on the rear surface 13b of the support base 13. The drain electrode 33 can be isolated from the gate electrode 23 because the drain electrode 33 is provided on the rear surface 13b of the support base 13.

The first surface 29b of the contact layer 29 forms a junction with the channel layer 19. The second surface 29c of the contact layer 29 forms a junction with the first surface 27b of the current blocking layer 27. The first surface 29b of the drift layer 29 forms a junction with the second surface 27c of the current blocking layer 27. The second surface 29c of the drift layer 29 forms a junction with the primary surface 13a of support base 13.

The rear surface of the channel layer 19 forms a junction with the end surface 29a of the drift layer 29, on the side surface 16a of the opening section 16. The rear surface of the channel layer 19 forms a junction with the end surface 25a of the drift layer 25. The rear surface of the channel layer 19 forms a junction with the end surface 27a of the current blocking layer 27.

In the heterojunction transistor 11, the support base 13 may comprise n-type GaN; the drift layer 25 may comprise undoped GaN; the current blocking layer 27 may comprise p⁺-type GaN; the contact layer 29 may comprise n⁺-type GaN; the channel layer 19 may comprise undoped GaN; and the carrier supply layer 21 may comprise AlGaN.

The gate electrode 23 can form a Schottky junction with the carrier supply layer 21. The carrier supply layer 21 and the channel layer 19 are provided between the gate electrode 23 and the end surface 27a of the current blocking layer 27. This example can provide a transistor in which channel carriers are controlled using the gate electrode 23 that forms a Schottky junction with a semiconductor.

Alternatively, the heterojunction transistor 11 may further comprise a gate insulating film that is provided on the carrier supply layer 21. The gate electrode 23 can form a junction with this gate insulating film. The carrier supply layer 21 and the channel layer 19 are provided between the gate insulating film and the end surface 27a of the current blocking layer 27. The present example can provide a transistor that has the gate electrode 23 for controlling channel carriers via the insulating film.

An example of the heterojunction transistor 11 is illustrated below.

Support base 13: n-type GaN (electron concentration: 1×10¹⁹ cm⁻³).

Channel layer 19: undoped GaN (electron concentration: 1×10¹⁶ cm⁻³, thickness: 30 nm).

Carrier supply layer 21: undoped AlGaN (thickness: 30 nm, Al composition ratio 0.25).

Drift layer 25: Si-doped n-type GaN (electron concentration: 1×10¹⁶ cm⁻³, thickness: 5 μm)

Current blocking layer 27: Mg-doped p⁺-type GaN (hole concentration: 1×10¹⁸ cm⁻³, thickness: 0.5 μm).

Contact layer 29: Si-doped n-type GaN (electron concentration: 1×10¹⁸ cm⁻³, thickness: 0.3 μm).

The above heterojunction transistor provides an example of a practicable structure.

The thickness of the drift layer 25 ranges from 1 μm to 10 μm. The Si concentration of the gallium nitride-based semiconductor of the drift layer 25 may range from 1×10¹⁵ cm⁻³ to 3×10¹⁶ cm⁻³. The thickness of the current blocking layer 27 may range from 0.1 μm to 2.0 μm, and the Mg concentration of the gallium nitride-based semiconductor of the current blocking layer 27 may range from 5×10¹⁶ cm⁻³ to 5×10¹⁸ cm⁻³. Preferably, the thickness of the contact layer 29 ranges from 0.1 μm to 1.0 μm, and the Si concentration of the gallium nitride-based semiconductor of the contact layer 29 is 1×10¹⁶ Cm⁻³ or higher. The semiconductor stack 15 provided with gallium nitride-based semiconductors having the above values make transistor characteristics superior.

The carrier supply layer 21 may comprise Al_{X}Ga_{1-X}N (0<X<1), and the thickness of the carrier supply layer 21 may range from 5 nm to 40 nm. The channel layer 19 may comprise undoped GaN, and the thickness of the channel layer 19 may range from 20 nm to 400 nm. The carrier supply layer 21 and the channel layer 19 having the above values between the gate electrode 23 and the current blocking layer 27 can make the transistor with characteristics superior.

The operation of the heterojunction transistor 11 is explained next. The turning-on and turning-off of the heterojunction transistor 11 is controlled through application of voltage to the gate electrode 23. When the heterojunction transistor 11 is not in conduction state, no current flows between the source electrode 31 and the drain electrode 33 of the heterojunction transistor 11. When the heterojunction transistor 11 is in conduction state, carriers flow from the source electrode 31 to the contact layer 29. Carriers flow from the contact layer 29 into the channel layer 19. The channel of two-dimensional gas channel is formed by virtue of gate bias, and hence the carriers can flow through the channel created just below the gate electrode. The carriers flowing through the channel are drawn in response to drain voltage to flow from the channel layer 19 into the drift layer 25. The carriers travelling through the drift layer 25 reach the drain electrode 33 via the support base 13.

In a useful embodiment, the end surface 25a of the drift layer 25 preferably includes the c-plane of the semiconductor layer 25. Preferably, the end surface 27a of the current blocking layer 27 includes the c-plane of the semiconductor layer 27. Preferably, the end surface 29a of the contact layer 29 includes the c-plane of the semiconductor layer 29. Using the c-plane or a vicinal surface close to the c-plane can reduce incorporation of impurities, such as oxygen, during growth of semiconductor layers on the side surface 16a of the opening section 16.

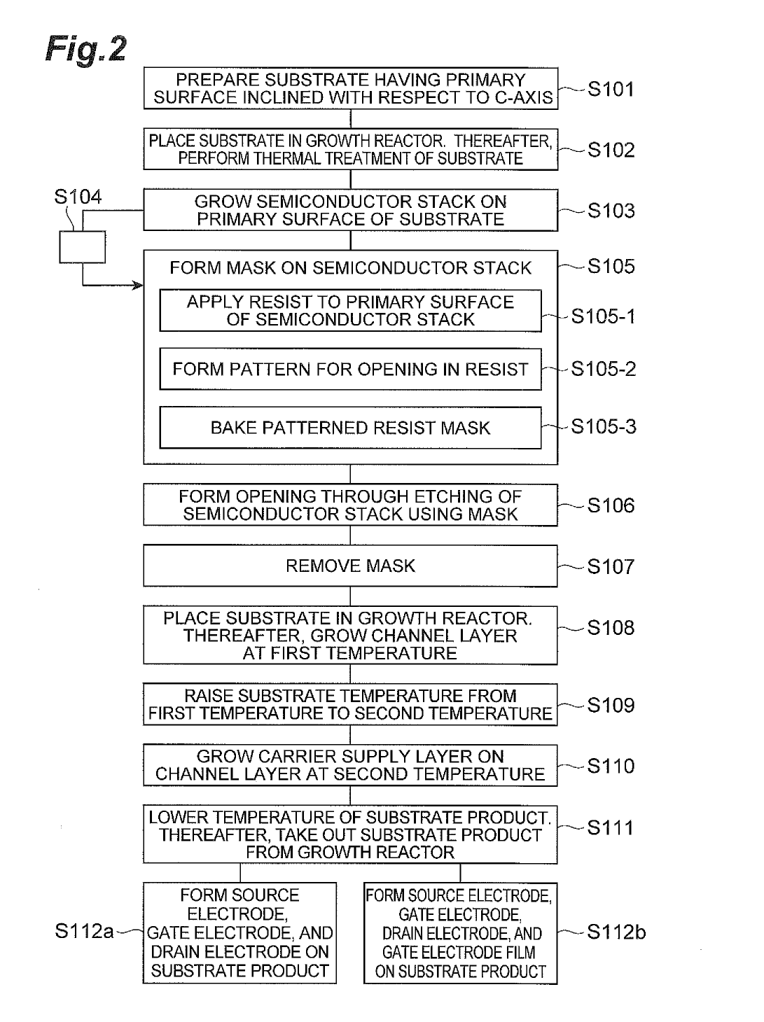

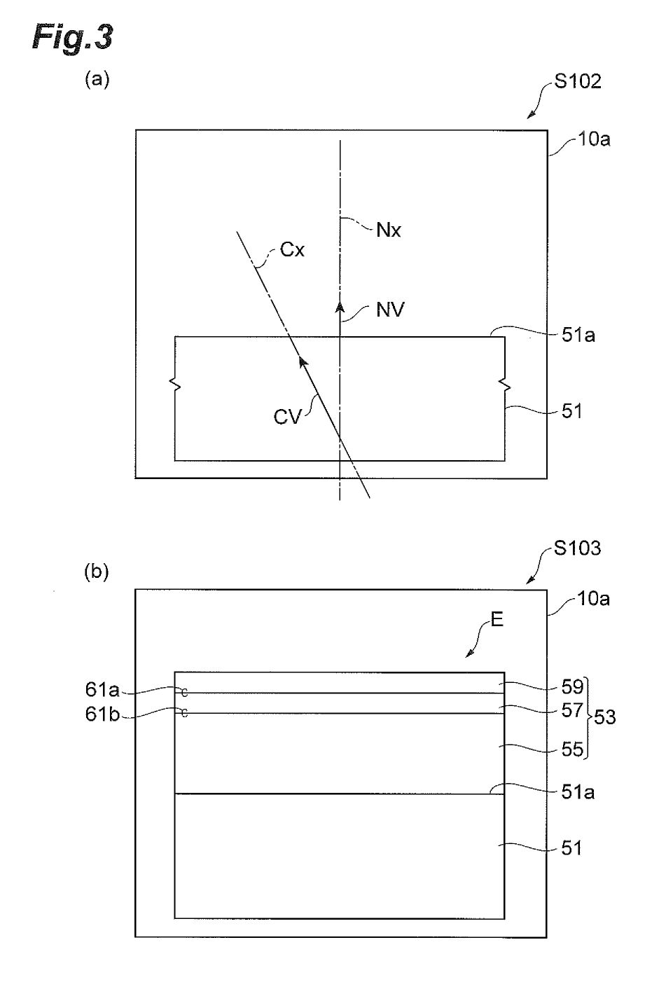

FIG. 2 is a flowchart showing the major steps of a method for fabricating a heterojunction transistor according to the present embodiment. FIG. 3 to FIG. 6 show schematic diagrams illustrating the major processes of a method for fabricating the heterojunction transistor according to the present embodiment.

In step S101, a conductive substrate (in Part (a) of FIG. 3, the substrate is denoted by the reference sign “51”) is prepared, and the conductive substrate has a semipolar primary surface 51a of a group III nitride semiconductor. For instance, a group III nitride semiconductor substrate may be used as the conductive substrate 51. The group III nitride semiconductor substrate may comprise, for instance, GaN, AlN or the like. The primary surface 51a of the conductive substrate 51 is selected in such a manner that a desired surface orientation can be provided on a side surface of an opening that is formed in a subsequent process. The inclination angle of the primary surface 51a ranges from 5 degrees to 40 degrees defined with respect to the reference axis Cx (vector CV) indicating the direction of the c-axis of the substrate.

In step S102, the group III nitride semiconductor substrate 51 is disposed in a growth reactor 10a, and thereafter, the group III nitride semiconductor substrate 51 is subjected to thermal cleaning, as illustrated in Part (a) of FIG. 3. The thermal cleaning is carried out, for instance, through thermal treatment of the group III nitride semiconductor substrate 51 in an atmosphere that contains ammonia and hydrogen. The duration of time for the thermal treatment is, for instance, about 10 minutes. The thermal treatment temperature is, for instance, of about 1030 degrees Celsius. The pressure in the reactor is, for instance, 100 Torr.

In step S103, a semiconductor stack 53 is grown on the primary surface 51a of the substrate 51, to form an epitaxial substrate E, as illustrated in Part (b) of FIG. 3. In the formation of the semiconductor stack 53, a drift layer 55 comprising a first conductivity type gallium nitride-based semiconductor, a current blocking layer 57 comprising a second conductivity type gallium nitride-based semiconductor; and a contact layer 59 for the first conductivity type gallium nitride-based semiconductor are grown, in this order, on the primary surface 51a of the substrate 51. For instance, metal-organic chemical vapor deposition can be applied to the growth herein. The drift layer 55 comprises, for instance, 5 μm-thick Si-doped GaN; the current blocking layer 57 comprises, for instance, 0.5 μm-thick Mg-doped p-type GaN; and the contact layer 59 comprises, for instance, 0.2 μm-thick Si-doped n⁺-type GaN. The thickness of the semiconductor stack 53 can be 5.7 μm. The surface orientation of junctions 61a, 61b in the semiconductor stack 53 is identical to the surface orientation of the primary surface 51a of the substrate 51.

In step S104, the semiconductor stack 53 and/or substrate is measured by X-ray diffraction to determine the surface orientation of the primary surface 51a and/or 53a with a view to optimization of etching conditions. A desired opening can be formed in the semiconductor stack 53, through adjustment of the etching conditions and so forth, on the basis of the results of X-ray diffraction measurement.

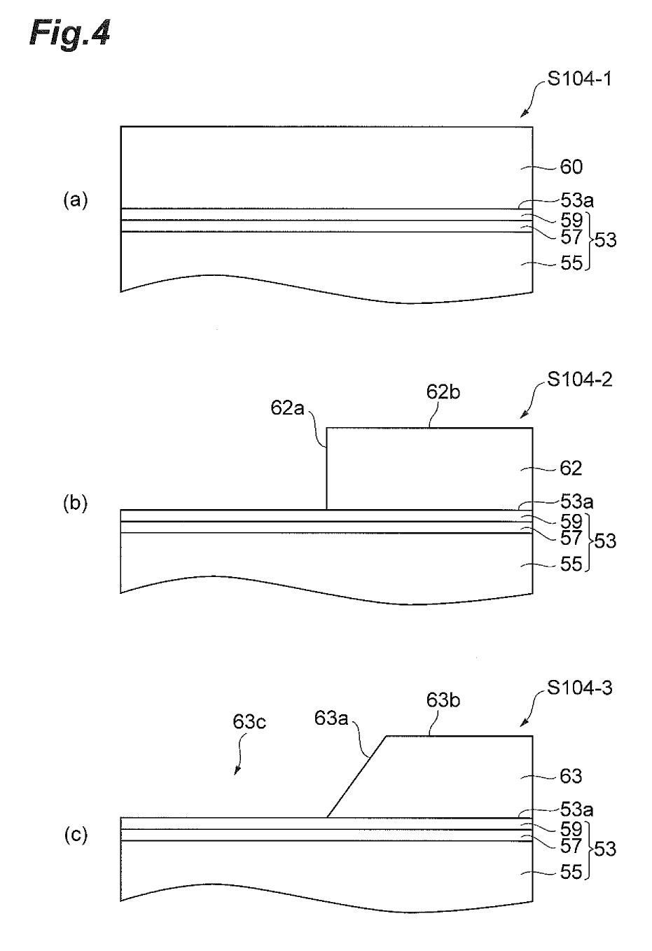

The epitaxial substrate E is taken out from the growth reactor 10a, and thereafter, in step S104, a mask is formed on the primary surface 53a of the semiconductor stack 53. Firstly, in step S105-1, resist is applied onto the primary surface 53a of the semiconductor stack 53, to form a resist film 60, as illustrated in Part (a) of FIG. 4. For instance, the thickness of the resist film 60 may range from 1 μm to 5 μm. In step S105-2, a pattern is applied to the resist film 60 by use of photolithography to form a patterned resist layer 62, as illustrated in Part (b) of FIG. 4. The pattern defines the shape of the opening section. The resist layer 62 comprises a side surface 62a and a top surface 62b that are formed by developing. In step S105-3, the patterned resist layer 62 is baked, to thereby form a baked patterned resist layer, i.e. a mask 63, as illustrated in Part (c) of FIG. 4. The mask 63 comprises a sloping side surface 63a and a top surface 63b. The sloping side surface 63a of the mask 63 is actually not a flat surface. The baking enhances the inclination of the line segment that joins the edge of the flat top surface of the resist and the base point, located on the primary surface 53a, of the inclined side surface 63a, in comparison with that before baking. The baking time depends upon the type and thickness of the resist, but may be, for instance, 5 minutes at the temperature of 90 degrees Celsius in a nitrogen atmosphere. The mask 63 has an opening 63c that defines the shape and position of the opening to be formed, in the semiconductor stack 53.

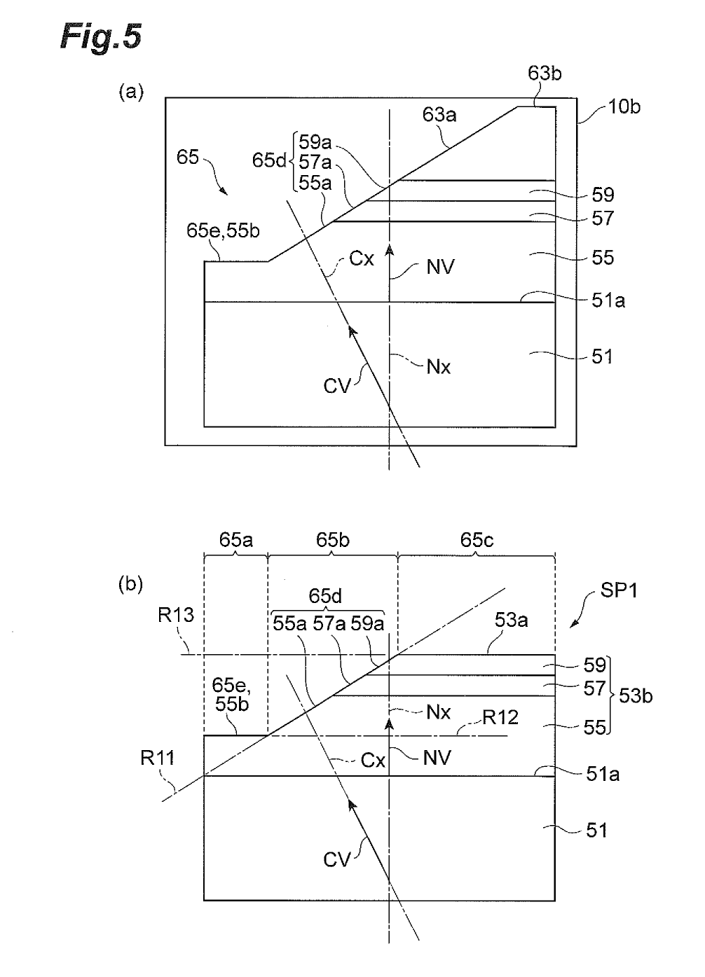

After the mask 63 has been formed by photolithography, the epitaxial substrate E is disposed, in step S106, in an etching device 10b illustrated in Part (a) of FIG. 5. The semiconductor stack 53 is dry-etched using this device 10b and the mask 63. Dry etching may be, for instance, reactive ion etching (RIE). An etchant comprising an inert gas and a chlorine-based etchant (e.g., Cl₂ gas) can be used as the etchant. As the inert gas, for instance, argon, neon, nitrogen or the like can be used. An opening 65 is formed in the semiconductor stack 53 through dry etching using the mask 63. As a result of the formation of opening, a semiconductor stack 53b provided with the opening 65 has been formed. During the etching, the inclined side surface 63a of the mask 63 is etched off, and the edge of the flat top surface 63b recedes as the etching progresses. During the etching, moreover, the inclination of the side surface 63a of the mask 63 is transferred to the shape of the side surface of the opening 65 of the semiconductor stack 53. The above method is one of methods for imparting inclination to the side surface of the opening 65 of the semiconductor stack 53, but the present invention is not limited to that method.

The opening 65 reaches the drift layer 55 from the contact layer 59 of the surface 53a. The opening 65 is defined by a side surface 65d and a bottom surface 65e. A side surface 55a and a top surface 55b of the drift layer 55, a side surface 57a of the current blocking layer 57, and a side surface 59a of the contact layer 59 appear at the side surface 65d and the bottom surface 65e of the opening 65. The top surface 55b of the drift layer 55 is exposed at the bottom surface 65e of the opening 65.

In step S107, the mask 63 is removed, as illustrated in Part (b) of FIG. 5, so that a substrate product SP1 is formed. In the substrate product SP1, the opening 65 has first to third portions 65a, 65b, and 65c. The top surface 55b (bottom surface 65e) of the drift layer 55 is exposed at the first portion 65a. In the second portion 65b, the side surface 65d of the opening 65 extends obliquely from the top surface 55b of the drift layer 55 up to the surface 53a of the semiconductor stack 53b. The surface 53a (surface of the contact layer 59) of the semiconductor stack 53b is exposed in the third portion 65c.

A single opening 65 is depicted in Part (b) of FIG. 5, but the substrate 51 has multiple openings arrayed thereon. Accordingly, the semiconductor stack 53b has a shape comprising a mesa shape, or a recess (for instance, a groove), depending upon the shape of the opening 63. The side surface 65d is inclined with respect to the primary surface 51a of the substrate 51, and is inclined with respect to the surface 53a of the semiconductor stack 53b. The angle of specific inclination of the side surface 65d can be controlled through etching in which the mask 63 is utilized.

If required, prior to the etching step, it is preferable that the surface orientation of the semiconductor be inspected by X-ray diffraction in step S104 to obtain information of the semiconductor surface orientation. The etching conditions can be adjusted in accordance with the results of the estimation of crystal orientation. Adjusting the conditions is suitable in terms of controlling the inclination of the side surface 65a of the semiconductor stack 65. If required, the resist thickness, light exposure conditions, and/or bake conditions can also be adjusted on the basis of the results of the above estimation. The step of X-ray diffraction can be performed before etching, and after formation of the semiconductor stack 53.

The side surface 65d extends, over the entirety thereof, along a reference plane R11. The reference plane R11 is inclined with respect to both the primary surface 51a of the substrate 51 and the normal line of the primary surface 51a of the substrate 51. The bottom surface 65e of the opening 65 extends along a reference plane R12, and the primary surface 53a of the semiconductor stack 53b extends along a reference plane R13. The angle formed by the c-axis and the normal line of the reference plane R11 is smaller than the angles formed by the normal lines of the reference planes R12, R13 and the c-axis. In a preferred example, the primary surface 53a of the semiconductor stack 53b can be substantially parallel to the primary surface 51a of the substrate 51. The angles formed by the reference plane R11 (i.e. the side surface 65d) and the reference planes R12, R13 (primary surface 53a, bottom surface 65e) can range, for instance, from 5 degrees to 40 degrees.

Prior to growth of the channel layer and the carrier supply layer, if necessary, the substrate product SP1 can be pre-treated (for instance, cleaned) and be placed thereafter in the growth reactor 10a.

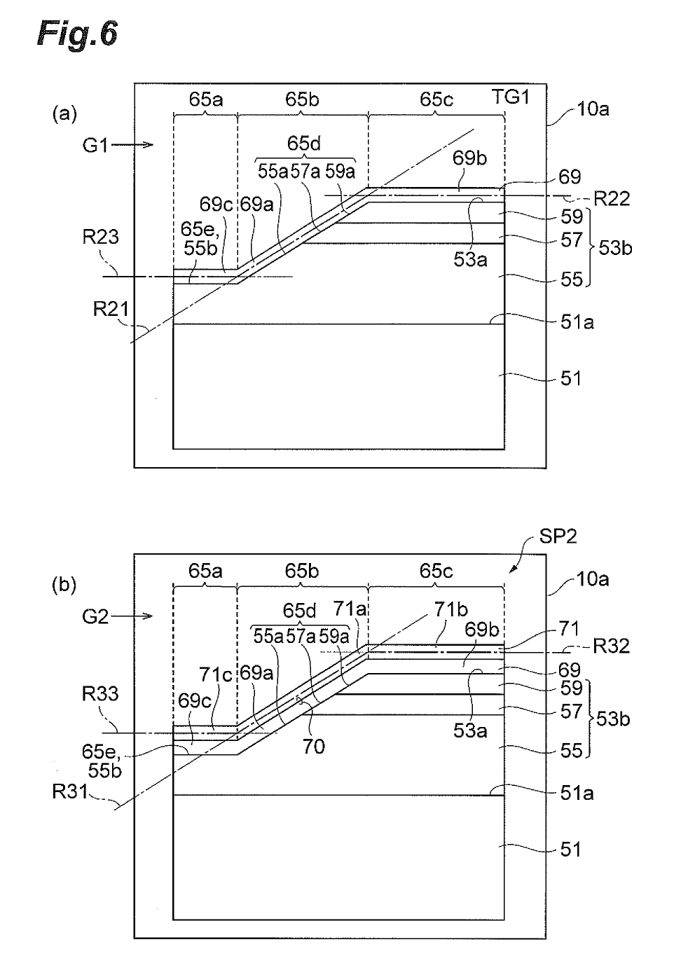

In step S108, a raw material gas G1 that comprises ammonia and a group III element raw material is supplied to the growth reactor 10a to grow a channel layer 69, at a growth temperature TG1, on the primary surface 53a of the semiconductor stack 53b and on the side surface 65d and the bottom surface 65e of the opening 65, as illustrated in Part (a) of FIG. 6. The channel layer 69 comprises an undoped gallium nitride-based semiconductor. The channel layer 68 comprises a first portion 69a, a second portion 69b and a third portion 69c. The first portion 69a is grown on the side surface 65d of the opening 65, and extends along a reference plane R21. The reference plane R21 is inclined with respect to the primary surface 51a of the substrate 51. The normal line of the reference plane R21 is, for instance, within an angle range of −10 degrees to +10 degrees with respect to the c-axis, and, in a preferred example, is substantially perpendicular to the c-axis of the gallium nitride-based semiconductor of the channel layer 69. The second portion 69b is grown on the primary surface 53a of the semiconductor stack 53b, and extends along a reference plane R22 that is perpendicular to the normal axis Nx. The first portion 69a is inclined with respect to the reference plane R21. The third portion 69c is grown on the bottom surface 65e of the opening 65, and extends along a reference plane R23. The first portion 69a is inclined with respect to the reference planes R22, R23. In a preferred example, the shape of the bottom surface 65e of the opening section 65 depends on the etching conditions and the material and shape of the mask. In a preferred example, the reference plane R23 is substantially parallel to the reference plane R22, and the reference plane R23 and the reference plane R22 are parallel to the primary surface 51a of the substrate 51.

A portion of the channel layer 69 is grown on the side surface 65d of the semiconductor stack 65, such that the oxygen concentration of this portion can be made lower than 1×10¹⁶ cm⁻³ thanks to the surface orientation of the side surface 65d. Drain leakage caused by the oxygen concentration in the channel layer 69 can be thus reduced.

The side surface 57a of the current blocking layer 57 is inclined at an angle of 5 degrees or more with respect to the reference axis Cx. Therefore, this allows avoiding increases in on-resistance which is caused by increases in channel length. The end surface 57a of the current blocking layer 57 is inclined at an angle of 40 degrees or less with respect to the reference axis Cx, and hence it becomes possible to avoid increases in the concentration of oxygen, which are derived from the surface orientation, in the channel layer 69 that is grown thereon.

In step S109, the substrate temperature is raised from the growth temperature TG1 to a growth temperature TG2, after growth of the channel layer 69 and before growth of a carrier supply layer 71. This change in temperature is performed for instance while ammonia flow is supplied to the growth reactor 10a. When the channel layer 69 comprises, for instance, GaN and the carrier supply layer 71 comprises, for instance, AlGaN, the growth temperature TG1 is, for instance, 950 degrees and the growth temperature TG2 is, for instance, 1080 degrees. The growth temperature TG1 ranges, for instance, from 900 degrees Celsius to 1100 degrees Celsius, and the growth temperature TG2 ranges, for instance, from 1000 degrees Celsius to 1200 degrees Celsius.

The primary surface 53a of the semiconductor stack 53 is inclined, at an angle ranging from 5 degrees to 40 degrees, with respect to the reference axis Cx. Accordingly, the degree of incorporation of oxygen into the channel layer 69 can be reduced, without lowering of the growth temperature TG1, during growth of the channel layer 69 on the inclined surface 65d of the semiconductor stack 65. Further, the period over which the substrate temperature is raised from the growth temperature TG1 to the growth temperature TG2 is not made lengthened, because the channel layer 69 is grown without lowering of the growth temperature TG1. Accordingly, it becomes possible to reduce migration of atoms at the surface of the channel layer 69 during the above raise in temperature, and to avoid deformation of the surface of the channel layer.

Further, the substrate temperature can be sufficiently stabilized to the growth temperature TG2 without lengthening of the period over which the substrate temperature is raised from the growth temperature TG1 to the growth temperature TG2. Once the substrate temperature has been sufficiently stabilized at the temperature TG2, a interface 70 is formed thereafter between the channel layer 69 and the carrier supply layer 71 that are subsequently grown. Accordingly, it becomes possible to avoid formation of the interface 70 with low quality.

In step S110, a raw material gas G2 that comprises ammonia and a group III element raw material is supplied to the growth reactor 10a, to thereby grow the carrier supply layer 71 at the growth temperature TG2 on the primary surface 53a of the semiconductor stack 53b, and on the side surface 65d and the bottom surface 65e of the opening 65, as illustrated in Part (b) of FIG. 6. The carrier supply layer 71 forms a heterojunction 70 with the channel layer 69. The carrier supply layer 71 comprises a group III nitride semiconductor. The carrier supply layer 71 comprises a first portion 71a, a second portion 71b, and a third portion 71c. The first portion 71a is grown on the side surface 65d of the opening 65, and extends along a reference plane R31. The reference plane R31 is inclined with respect to the primary surface 51a of the substrate 51. The normal line of the reference plane R31 is, for instance, within an angle range of −10 degrees to +10 degrees with respect to the c-axis. In a preferred example, the reference plane R31 can be substantially perpendicular to the c-axis of the gallium nitride-based semiconductor of the carrier supply layer 71. The second portion 71b is grown on the primary surface 53a of the semiconductor stack 53b, and extends along a reference plane R32. The first portion 71a is inclined with respect to the reference plane R32. The third portion 71c is grown on the bottom surface 65e of the opening 65, and extends along a reference plane R33. The first portion 71a is inclined with respect to the reference plane R33. In the present example, the reference plane R33 is substantially parallel to the reference plane R32, and the reference plane R33 and the reference plane R32 are parallel to the primary surface 51a of the substrate 51. The bandgap of the group III nitride semiconductor of the carrier supply layer 71 is greater than the bandgap of the gallium nitride-based semiconductor of the channel layer 69. The junction 70 is formed by the channel layer 69 and the carrier supply layer 71, and a two-dimensional carrier gas layer is formed along the junction 70.

After growth of the carrier supply layer 71 is complete, the temperature of the substrate product SP2 begins to lower from the growth temperature TG2. After growth of the carrier supply layer 71 is complete, the temperature is lowered while exposing the surface 71a of the carrier supply layer 71 to a predetermined atmosphere at a temperature not higher than the growth temperature TG2 of the carrier supply layer 71. The predetermined atmosphere comprises nitrogen (N₂) but does not comprise ammonia.

In step S111, the temperature of the substrate product SP2 is lowered, and the substrate product SP2 is taken out therefrom. In the electrode formation process in step S112a or step S112b, a gate electrode is formed on the carrier supply layer 71. More specifically, the following formations are carried out in the electrode formation process: the formation of a source electrode that forms a contact with the semiconductor layers 57, 59 of the semiconductor stack 53b; the formation of a drain electrode that forms a contact with the back side 51b of the substrate 51; the formation of a gate insulating film 77; and the formation of a gate electrode that forms a contact on the gate insulating film 77.

The source electrode can be formed on the primary surface 53a of the semiconductor stack 53b. The source electrode supplies potential to the current blocking layer 57 and the contact layer 59. The source electrode 73 also supplies carriers that flow through the channel layer 69. The carriers flow through the two-dimensional carrier gas to the drift layer 55. In this manufacturing method, the source electrode supplies potential to the current blocking layer 57 and the contact layer 59, and hence the current blocking layer 57 functions as a back gate to the channel layer 69.

### EXAMPLES

### Production of an Epitaxial Substrate

A gallium nitride film is formed by MOCVD. Trimethyl gallium is used as the gallium raw material. High-purity ammonia is used as a nitrogen raw material. Purified hydrogen is used as a carrier gas. The purity of the high-purity ammonia is 99.999% or higher, and the purity of the above purified hydrogen is 99.999995% or higher. Hydrogen base silane is used as an n-type dopant, and bis(cyclopentadienyl)magnesium is used as a p-type dopant. A conductive gallium nitride substrate is used as the substrate. The size of the substrate is 2 inches. Firstly, the substrate is cleaned in an atmosphere of ammonia and hydrogen at a temperature of 1030 degrees Celsius and a pressure of 100 Torr. Thereafter, the temperature is raised to 1050 degrees Celsius, and then a gallium nitride layer is formed at a pressure of 200 Torr and a V/III molar ratio of 1500. In the present example, the off-angle of the primary surface of the GaN substrate can be 18 degrees.

A 5 μm-thick undoped GaN drift layer, a 0.5 μ-thick p-type AlGaN current blocking layer and a 0.2 μm-thick n-type GaN cap layer (contact layer) are grown, in this order, on the gallium nitride substrate. The Si concentration of the drift layer is 1×10¹⁶ cm⁻³, the Mg concentration of the barrier layer is 1×10¹⁸ cm⁻³, and the Si concentration of the cap layer is 1×10¹⁸ cm⁻³. The above film deposition results in the fabrication of an epitaxial substrate having a semiconductor stack for an npn structure on the gallium nitride substrate.

Production of a Device Structure

An opening section is formed in the epitaxial substrate. In order to fabricate a mask for this formation, the epitaxial film surface is coated with resist, followed by formation of a pattern in the resist by photolithography. An opening section is formed using this mask in the epitaxial substrate by reactive ion etching (RIE) to make a substrate product having an opening. Regarding the inclination angle of the inclined surface of the opening section, the angle difference between the normal line of the inclined surface of the opening section and the reference axis that extends in the c-axis direction of the GaN substrate is preferably larger than −10 degrees and smaller than +10 degrees. Re-growing undoped GaN as the channel layer on a surface inclined at an inclination angle outside the above angle range results in that the channel layer is provided with deficient uniformity of thickness.

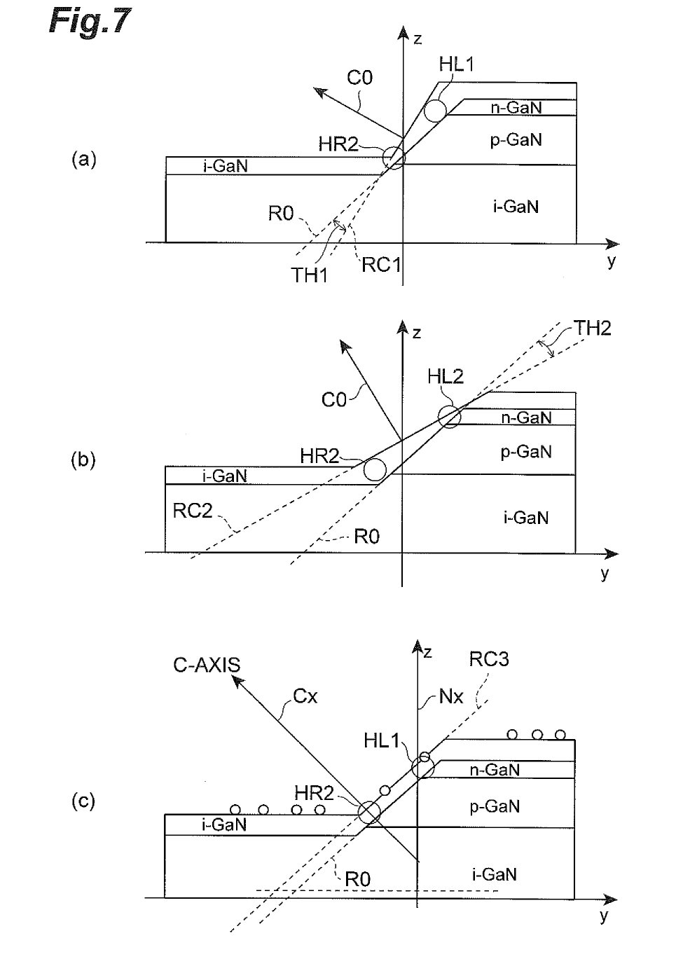

FIG. 7 is a set of diagrams for explaining inclination of a side surface of an opening section and uniformity of the channel layer thickness. The coordinate axes correspond to the coordinate axes S illustrated in FIG. 1. Since the side surface of the opening section has a surface orientation of the c-plane or close to the c-plane, the surface of the channel layer tends to have a c-plane orientation. Part (a) of FIG. 7 illustrates the configuration of a channel layer which is grown on the side surface, which has a comparatively large inclination, of the opening section. The side surface of the opening section extends along a reference plane R0, and the surface of the channel layer extends along a reference plane RC1 that is substantially perpendicular to the c-axis. When an angle TH1 formed by the reference plane RC1 and the reference plane R0 is excessively large, the channel layer has a thickness which increases gradually on the inclined surface of the opening section in the direction from the bottom surface of the opening section to the top surface of the semiconductor stack. Accordingly, the uniformity of thickness of the channel layer is not excellent. When the thickness of the channel layer is excessively large at the upper end of the side surface of the current blocking layer, an electric field from the gate electrode does not reach deep into the channel layer, and accordingly the leakage current increases. When the thickness of the channel layer is excessively small on the lower end of the side surface of the current blocking layer, p-type dopant diffusion from the underlying p-type layer increases the on-resistance thereof.

Part (b) of FIG. 7 illustrates the configuration of a channel layer that is grown on the side surface of an opening section having a comparatively small inclination. The side surface of the opening section extends along the reference plane R0, and the surface of the channel layer extends along a reference plane RC2 that is substantially perpendicular to the c-axis. When an angle TH2 formed by the reference plane RC2 and the reference plane R0 is excessively large, the thickness of the channel layer increases gradually on the inclined surface of the opening section in the direction from the top surface of the opening section to the bottom surface of the semiconductor stack. Accordingly, the uniformity of thickness of the channel layer is not excellent. When the thickness of the channel layer at the upper end of the side surface of the current blocking layer is excessively small, the cross-section of the channel layer through which channel current flows is made small, and the small cross-sectional area increases the on-resistance. When the thickness of the channel layer on the lower end of the side surface of the current blocking layer is excessively large, the electric field of the gate electrode does not reach deep into the channel layer, and accordingly the leakage current increases.

Part (c) of FIG. 7 illustrates the configuration of a channel layer that is grown on the side surface, having substantially the same inclination as that of the primary surface of the substrate with respect to the c-axis, of an opening section. The side surface of the opening section has a crystal orientation of the c-plane or close to the c-plane, and hence the surface of the channel layer tends to have the orientation of c-plane. The side surface of the opening section extends along the reference plane R0, and the surface of the channel layer extends along a reference plane RC3 that is substantially perpendicular to the c-axis. When the reference plane RC3 and the reference plane R0 are substantially parallel to each other, the thickness of the channel layer on the inclined surface of the opening section has a small change in the direction from the bottom surface of the opening section to the top surface of the semiconductor stack. The uniformity of thickness of the channel layer is accordingly excellent. When the thickness of the channel layer at the upper end of the side surface of the current blocking layer is substantially identical to the thickness of the channel layer on the lower end of the side surface of the current blocking layer, the electric field of the gate electrode reaches sufficiently deep into the channel layer; thereby suppressing the leakage current and preventing on-resistance from increasing due to the influence of p-type dopant diffusion from the underlying p-type layer.

In the present example, the crystal orientation can be evaluated on the basis of a ω2θ scan of XRD, and the supply ratio of reactive gas (chlorine or the like)/inert gas (rare gas) is adjusted in accordance with that crystal orientation. This adjustment allows the etching rate of RIE for forming the inclined surface to change in the substrate vertical direction, thereby adjusting the inclination angle of the opening section. In turn, this allows the inclination angle of the side surface of the opening section that is created by etching to lie within the angle difference range explained above.

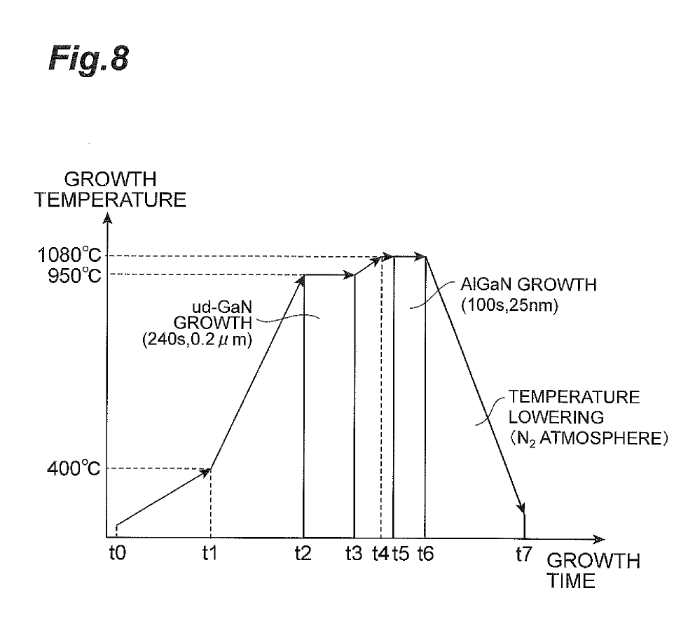

After removal of the resist mask and cleaning of the substrate, the channel layer and the carrier supply layer are grown in accordance with the temperature sequence for re-growth illustrated in FIG. 8. Firstly, at time t0, the substrate product is introduced in an MOCVD apparatus, and the substrate temperature is raised to 400 degrees Celsius at time t1. The temperature is further raised to 950 degrees Celsius in an atmosphere comprising ammonia and hydrogen, and thermal cleaning is performed thereafter. Next, a group III organometallic raw material (TMG) is supplied, at time t2, to the growth reactor while ammonia and hydrogen are continuously supplied to the growth reactor, thereby growing an i-GaN channel layer having a thickness of 100 nm. At time t3, supply of the group III organometallic raw material is stopped to terminate growth of the channel layer. Thereafter, the substrate temperature is raised to a temperature of 1080 degrees Celsius in an atmosphere comprising ammonia and hydrogen, at time t4. At time t5, group III organometallic raw materials (TMG, TMA) are supplied into the growth reactor, to thereby grow an i-AlGaN carrier supply layer having a thickness of 25 nm. At time t6, supply of the group III organometallic raw materials is stopped to terminate growth of the carrier supply layer. Thereafter, the atmosphere of ammonia and hydrogen is changed to a nitrogen (N₂) atmosphere, followed by lowering of the substrate temperature down to room temperature. The substrate product is taken out from the growth reactor at time t7.

An insulating film is formed over the entire surface of the substrate product, and, thereafter, a source electrode and a drain electrode are formed on the front surface and the rear surface of the epitaxial substrate, respectively, and a gate electrode is formed on the side surface of the opening section by photolithography and ion beam vapor deposition.

As a result of these processes, a heterostructure transistor is formed in which increases in on-resistance can be suppressed, and drain leakage current is reduced.

When a c-plane GaN substrate is used for the formation of a structure for a vertical transistor, the i-GaN channel layer and the i-AlGaN electron supply layer are re-grown sequentially in the following formation. Herein, a physical process, namely etching, is applied thereto to form the underlying opening section having the inclined surface, and hence the inclined surface has no specific crystal orientation.

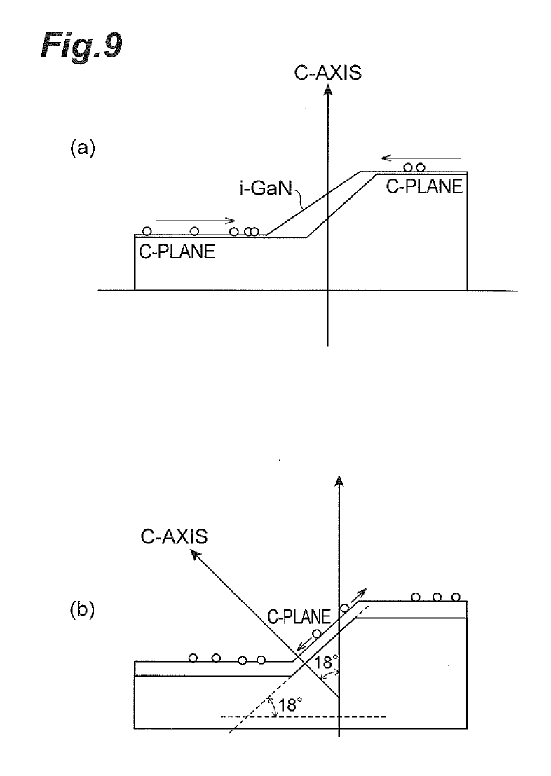

Accordingly, when a re-growth process in which i-GaN is deposited on the physically-formed underlying surface is carried out, a flat surface in the periphery of the inclined portion of the underlying surface is grown in the initial stage of the re-growth to have a surface orientation of a C-plane or its vicinal surface. As illustrated in Part (a) of FIG. 9, group III atoms that have not been consumed in the flat surface because of limitation of the uptake of raw material therein are taken up in substantial amounts into the rougher inclined surface. Accordingly, the growth rate in the vertical direction at the inclined surface becomes extremely high with respect to the C-plane, and uptake of more oxygen becomes more likely to occur during the epitaxial growth by virtue of the growth direction. As a result, the i-GaN channel layer that has been re-grown on the opening section has an unexpectedly large electron concentration. This constitutes a cause of transistor drain leakage.

In order to suppress growth in the C-axis vertical direction, as described above, the growth temperature of i-GaN is lowered to promote incorporation of raw material into the C-plane and to allow relatively reducing the uptake of raw material into the inclined surface section. From the viewpoint of crystal quality, the optimal growth temperature of i-AlGaN is set to be higher than that of i-GaN. The growth interruption period of time after the growth of i-GaN becomes longer such that the temperature rises to the growth temperature of i-AlGaN. In this case, substance migration occurs at the surface of the inclined surface that is exposed to the high-temperature atmosphere, and the shape of the inclined surface collapses during a longer interruption of growth. Therefore, lowering the growth temperature to reduce the uptake of oxygen is subjected to constraints. If the growth interruption period of time is not made longer, by contrast, the subsequent growth is initiated before the growth temperature has risen sufficiently for growth of i-AlGaN. This translates into a drop in crystallinity of i-AlGaN and/or the steepness of Al composition at the i-AlGaN/i-GaN interface. This drop gives rise in turn to an increase of the on-resistance, which is observed after formation of the device.

In the re-growth of the i-GaN channel layer and the i-AlGaN electron supply layer in the opening having an side surface of an significant inclination with respect to the C-plane, the growth rate of the inclined surface section becomes higher than that of the C-plane section of the flat surface. In particular, the incorporation of conductive impurities such as oxygen occurs more readily during growth of the i-GaN channel layer. This constitutes a cause of drops in drain breakdown voltage, which is observed after transistor formation.

Accordingly, the present embodiment provides a formation method and a structure of a vertical semiconductor element that are effective in improving the electric characteristics and reliability of a transistor. In the present embodiment, the crystal orientation of the primary surface of the substrate is inclined at an angle in the range of about 5 degrees to 40 degrees, which can be defined in an arbitrary direction of inclination with respect to the C-axis. A semiconductor stack is epitaxially grown on the substrate. A inclined surface is formed such that it is inclined with respect to the top surface of the semiconductor stack, and a flat surface different from the inclined surface is formed such that it is inclined with respect to the C-plane. The inclined surface has, in accordance with the substrate crystal orientation, an angle in the range of about 5 to 40 degrees with respect to the top surface of the semiconductor stack. The inclined surface has a structure that comprises either a C-plane surface or a vicinal surface comprising C-plane terraces and steps. A channel layer and an electron supply layer are re-grown on the inclined surface.

Prior to formation of a HEMT structure by use of re-growth, the opening with the inclined surface is formed so as to have a C-plane surface or a vicinal surface comprising C-plane terraces and steps therein, such that the flat surface in the opening and the primary surface of the semiconductor stack are inclined with respect to the C-plane. Then, the HEMT structure is formed on the structure of this surface by re-grown, which can avoid taking up group III atoms from the flat section into the inclined surface section, as illustrated in Part (b) of FIG. 9. Further, the growth direction of re-grown i-GaN becomes parallel to the C-axis, and the re-growth in the above direction allows the reduction in uptake of oxygen. Accordingly, it becomes possible to reduce drain leakage, caused by leakage in the i-GaN channel layer, of the transistor.

The C-plane or vicinal surface comprising C-plane terraces and steps is formed at the inclined surface of the opening section. Even if the growth temperature of i-GaN were raised, therefore, it would be possible to curtail the increase in growth rate defined in the direction vertical to the flat surface, and the period of time that temperature takes to reach the optimal temperature for the growth of i-AlGaN would not be made prolonged. As results, it becomes possible to avoid worsening, which is caused by growth temperature inadequate for the growth of i-AlGaN, of the i-AlGaN crystallinity and of the steepness of the Al composition at the i-AlGaN/i-GaN interface, and it becomes possible to avoid increases in transistor on-resistance caused by degradation of the quality of the interface for the two-dimensional electron gas.

The length of the side surface of the current blocking layer defines an effective channel for control of the two-dimensional electron gas, and hence a crystal orientation of the substrate set to an angle of 5 degrees or less with respect to the C-axis increases the channel length, whereby its on-resistance increases. A crystal orientation of the substrate with respect to the C-axis set to an angle of 40 degrees or more, by contrast, causes nitrogen to become exposed at the growth surface during epitaxial growth of the underlying section prior to formation of the opening section by RIE, whereby oxygen contamination occurs. The breakdown voltage of a pn-diode formed by the channel layer and the current blocking layer decreases due to the both influences of acceptor compensation in the current blocking layer and of excess donors in the channel layer. In this situation, an acceptor shortage in the current blocking layer translates into an increase in drain leakage. In particular, when the inclination angle from the C-axis exceeds 40 degrees, the i-GaN layer is contaminated with 1×10⁷ cm⁻³ or more of oxygen, whereby the breakdown voltage in the pn-diode structure section and the drain breakdown voltage are both lowered.

The scope of the present invention has been illustrated in the embodiments. However, one skilled in the art should understand that the arrangement and other details of the present invention may be changed without departing from the scope of the invention. All corrections and modifications relevant to the scope of the claims and the spirit of the invention should be included in the scope of the present invention.

### INDUSTRIAL APPLICABILITY

The present embodiment succeeds in providing a method of fabricating a nitride electronic device that allows reducing leakage caused by an increase in carrier concentration in the channel layer thereof. Further, the present embodiment allows providing a nitride electronic device having a structure that allows reducing leakage through avoidance of increases in carrier concentration in the channel layer.

### REFERENCE SIGNS LIST

10a . . . growth reactor; 11 . . . heterojunction transistor; 13 . . . conductive substrate; 15 . . . semiconductor stack; 16 . . . opening; 19 . . . channel layer; 20 . . . heterojunction; 21 . . . barrier layer; 23 . . . gate electrode; 25 . . . drift layer; 27 . . . current blocking layer; 29 . . . contact layer:\; 31 . . . source electrode; 33 . . . drain electrode; CR . . . crystal coordinate system; 51 . . . group III nitride semiconductor substrate; 53, 53b . . . semiconductor stack; 55 . . . drift layer; 57 . . . current blocking layer; 57 . . . contact layer; E . . . epitaxial substrate; 63 . . . mask; 65 . . . opening; 65d . . . side surface; 65e . . . bottom surface; R11, R12, R13, R31, R32, R33 . . . reference plane; 69 . . . channel layer; 71 . . . carrier supply layer; 73 . . . source electrode; 77 . . . gate insulating film; 79 . . . gate electrode.

1. A method for fabricating a nitride electronic device, comprising the steps of:
growing a semiconductor stack on a primary surface of a substrate;
forming a mask on the semiconductor stack;
etching the semiconductor stack using the mask to form an opening in the primary surface of the semiconductor stack, the opening having an inclined surface, the inclined surface being inclined with respect to a primary surface of the semiconductor stack; and
supplying a raw material gas to a growth reactor, after removal of the mask, to grow a channel layer on the primary surface and the inclined surface of the semiconductor stack at a first growth temperature, the raw material gas containing ammonia and a group III element raw material,
the primary surface of the substrate comprising a hexagonal-system group III nitride,
the semiconductor stack comprising a drift layer of a first gallium nitride-based semiconductor, a current blocking layer of a second gallium nitride-based semiconductor, and a contact layer of a third gallium nitride-based semiconductor,
the channel layer comprising an undoped gallium nitride-based semiconductor,
the inclined surface and the primary surface of the semiconductor stack extending along first and second reference planes, respectively,
a vector normal to the primary surface of the semiconductor stack being inclined at an angle, the angle ranging from 5 degrees to 40 degrees with respect to a reference axis, the reference axis indicating a c-axis direction of the hexagonal-system group III nitride, and
an angle formed by the reference axis and an axis normal to the first reference plane being smaller than an angle formed by the reference axis and an axis normal to the second reference plane.

2. The method for fabricating a nitride electronic device according to claim 1, further comprising the steps of:
raising a substrate temperature from the first growth temperature to a second growth temperature after growth of the channel layer; and
growing a carrier supply layer on the channel layer in the growth reactor at the second growth temperature to form a substrate product,
the carrier supply layer comprising a group III nitride semiconductor,
a bandgap of the group III nitride semiconductor of the carrier supply layer being greater than a bandgap of the gallium nitride-based semiconductor of the channel layer,
the channel layer comprising a first portion and a second portion, the first portion being grown on the inclined surface of the semiconductor stack, and the second portion being grown on the primary surface of the semiconductor stack,
the carrier supply layer comprises a first portion and a second portion, the first portion being grown on the first portion of the channel layer, and the second portion being grown on the second portion of the channel layer,
the first portion of the carrier supply layer being inclined with respect to the second reference plane, and
a vector normal to the second reference plane being inclined at an angle ranging from 5 degrees to 40 degrees with respect to a reference axis, the reference axis indicating a c-axis direction of the first gallium nitride-based semiconductor.

3. The method for fabricating a nitride electronic device according to claim 1,
wherein an oxygen concentration of the first portion of the channel layer is lower than 1×10¹⁷ cm⁻³.

4. The method for fabricating a nitride electronic device according to claim 1,
wherein a vector normal to the inclined surface of the semiconductor stack forms an angle in a range of larger than −10 degrees and smaller than +10 degrees with respect to a plane perpendicular to the reference axis of the hexagonal-system group III nitride.

5. The method for fabricating a nitride electronic device according to claim 1, further comprising the step of forming a gate electrode on the carrier supply layer after taking out the substrate product,
wherein the inclined surface of the opening comprises a side surface of the drift layer, a side surface of the current blocking layer, and a side surface of the contact layer,
the gate electrode is provided on the side surface of the current blocking layer, and
the side surface of the current blocking layer is inclined at an angle ranging from 5 degrees to 40 degrees with respect to a second portion grown on the primary surface of the semiconductor stack.

6. The method for fabricating a nitride electronic device according to claim 1,
wherein forming the mask on the semiconductor stack comprises the steps of:
patterning a resist applied to the semiconductor stack, the patterned resist having an edge, and the edge defining the opening; and
forming a sloping surface at the edge through thermal treatment of the patterned resist to form the mask, and
wherein in the etching, the mask and the semiconductor stack are etched by dry etching.

7. The method for fabricating a nitride electronic device according to claim 1,
wherein the substrate includes a conductive free-standing group III nitride substrate,
a vector normal to a primary surface of the free-standing group III nitride substrate is inclined at an angle in a range of 5 degrees to 40 degrees with respect to a plane perpendicular to the reference axis indicating the c-axis direction of the hexagonal-system group III nitride, and
the method further comprises the step of forming a drain electrode on a backside surface of the substrate.

8. The method for fabricating a nitride electronic device according to claim 1, wherein a combination of the first gallium nitride-based semiconductor of the drift layer, the second gallium nitride-based semiconductor of the current blocking layer, and the third gallium nitride-based semiconductor of the contact layer encompasses any one of n-type GaN/p-type GaN/n⁺-type GaN and n-type GaN/p-type AlGaN/n⁺-type GaN.

9. The method for fabricating a nitride electronic device according to claim 1, wherein a combination of the channel layer and the carrier supply layer encompasses any one of InGaN/AlGaN, GaN/AlGaN and AlGaN/AlN.

10. The method for fabricating a nitride electronic device according to claim 1, further comprising the step of forming a source electrode on the primary surface of the semiconductor stack after taking out the substrate product from the growth reactor,
wherein the source electrode provides potential to the current blocking layer and the contact layer,
the channel layer and the carrier supply layer form a junction, and a two-dimensional electron gas layer is formed along the junction, and
the source electrode provides carriers flowing through the channel layer.

11. The method for fabricating a nitride electronic device according to claim 1, further comprising the step of forming a gate electrode, the gate electrode forming a junction with the first portion of the carrier supply layer.

12. The method for fabricating a nitride electronic device according to claim 1, further comprising the steps of:
forming a gate insulating film on the first portion of the carrier supply layer; and
forming a gate electrode on the gate insulating film, the gate electrode forming a junction with the gate insulating film.

13. A nitride electronic device, comprising:
a support base comprising a hexagonal-system group III nitride, the support base having a vector normal to a primary surface thereof, the primary surface being inclined at an angle in a range of 5 degrees to 40 degrees with respect to a c-axis of the hexagonal-system group III nitride;
a semiconductor stack comprising a drift layer, a current blocking layer, and a contact layer, the drift layer, the current blocking layer and the contact layer being sequentially provided on the primary surface of the support base, and the semiconductor stack having an opening from the contact layer to the drift layer via the current blocking layer;
a channel layer provided on a side surface of the opening, the channel layer comprising a gallium nitride-based semiconductor;
a carrier supply layer provided on the side surface of the opening, the carrier supply layer comprising a group III nitride;
a gate electrode provided on the side surface of the opening;
a source electrode provided on a primary surface of the semiconductor stack; and
a drain electrode provided on any one of the semiconductor stack and the support base,
an oxygen concentration of the channel layer being lower than 1×10¹⁷ cm⁻³,
the side surface and the primary surface of the semiconductor stack extending along first and second reference planes, respectively,
the primary surface of the semiconductor stack being inclined at an angle in a range of 5 degrees to 40 degrees with respect to a plane, the plane being perpendicular to a reference axis, and the reference axis indicating a c-axis direction of the hexagonal group III nitride,
an angle formed by the reference axis and an axis normal to the first reference plane being smaller than an angle formed by the reference axis and an axis normal to the second reference plane,
the drift layer comprising a first gallium nitride-based semiconductor,
the current blocking layer comprising a second gallium nitride-based semiconductor,
the contact layer comprising a third gallium nitride-based semiconductor,
the channel layer being provided between the carrier supply layer and the side surface of the opening, and
a bandgap of the group III nitride of the carrier supply layer being greater than a bandgap of the gallium nitride-based semiconductor of the channel layer.

14. The nitride electronic device according to claim 13,
wherein the first gallium nitride-based semiconductor of the drift layer includes Si-doped n-type GaN, a thickness of the drift layer ranges from 1 μm to 10 μm, and an Si concentration of the first gallium nitride-based semiconductor ranges from 1×10¹⁵ cm⁻³ to 3×10¹⁶ cm⁻³,
the second gallium nitride-based semiconductor of the current blocking layer includes Mg-doped p-type GaN, a thickness of the current blocking layer ranges from 0.1 μm to 2.0 μm, an Mg concentration of the second gallium nitride-based semiconductor ranges from 5×10¹⁶ cm⁻³ to 5×10¹⁸ cm⁻³, and
the third gallium nitride-based semiconductor of the contact layer includes Si-doped n-type GaN, a thickness of the contact layer ranges from 0.1 μm to 1.0 μm, and an Si concentration of the third gallium nitride-based semiconductor is 1×10¹⁶ cm⁻³ or higher.

15. The nitride electronic device according to claim 13,
wherein the carrier supply layer comprises Al_{X}Ga_{1-X}N (0<X<1),
a thickness of the carrier supply layer ranges from 5 nm to 40 nm,
the channel layer comprises undoped GaN, and
a thickness of the channel layer ranges from 20 nm to 400 nm.

16. The nitride electronic device according to claim 13, wherein the side surface of the semiconductor stack forms an angle in a range of larger than −10 degrees and smaller than +10 degrees with respect to a plane perpendicular to the reference axis of the c-axis direction of the hexagonal-system group III nitride.

17. The nitride electronic device according to claim 13, wherein the gate electrode forms a junction with the first portion of the carrier supply layer.

18. The nitride electronic device according to claim 13, further comprising:
a gate insulating film provided on the carrier supply layer,
the gate electrode forming a junction with the gate insulating film.
